(19) United States
(12) Patent Application Publication
(10) Pub. No.: US 2009/0147370 A1
(43) Pub. Date: Jun. 11, 2009

(54) NANOPARTICLE AND NANOCOMPOSITE FILMS

(76) Inventors: Ivan Parkin, Milton Keynes (GB); Michael Wilson, London (GB); Robert Palgrave, Oxford (GB)

Correspondence Address: NIXON & VANDERHYE, PC, 901 NORTH GLEBE ROAD, 11TH FLOOR, ARLINGTON, VA, 22203, US

(21) Appl. No.: 12/091,816

(22) PCT Filed: Oct. 30, 2006
(86) PCT No.: PCT/GB2006/004032

§ 371 Date: Aug. 22, 2008

(30) Foreign Application Priority Data
Oct. 31, 2005 (GB) 0522234.4
Feb. 21, 2006 (GB) 0603433.4

(51) Int. Cl. G02B 5/26; C23C 16/30; C23C 16/448

(52) U.S. Cl. 359/634; 427/314; 427/255.28; 428/469; 428/432

(57) ABSTRACT

The use of an aerosol transport operation for producing a nanoparticle film or a nanocomposite film on a substrate, wherein the substrate is heated.

The present invention relates to the use of an aerosol transport operation for producing nanoparticle films or nanocomposite films on a substrate. The invention also relates to a process for the production of such films, to films produced using the process and to gold nanoparticle or nanocomposite films having particular properties.

### BACKGROUND

Nanoparticles are a major research focus worldwide, and a variety of different shapes and compositions can now be produced. Many technological applications of these particles will depend on their incorporation into a host matrix; the result being a nanocomposite, which selves both to immobilize the particles and render them chemically inert. In addition, the incorporation of nanoparticles into a matrix can change the properties of both the particle and the host. Semiconductor/metal nanocomposites are known. In particular, noble metal nanoparticles may be incorporated into a semiconductor matrix. Semiconductor/metal nanocomposites have been exploited in improved photocatalysts, photoanodes, and photochromic and electrochromic films.

Several strategies for production of semiconductor/metal composites have been developed, for example: high energy ion implantation and spin coating with a solution of metal ions followed by photocatalytic reduction or heat treatment, sol-gel using both semiconductor and nanoparticle precursors, the related technique of liquid phase deposition, multitarget magnetron sputtering deposition, chemical vapour deposition (CVD) using a separate precursor for each phase, and layer-by-layer deposition of metal particles and semiconductor material, for example laser ablation using alternate metal and semiconductor targets. In these methods, particles are formed in situ or concurrently with the matrix. There are therefore limits on the type and complexity of nanoparticle that can be incorporated, imposed by the deposition conditions.

Aerosol assisted chemical vapour deposition (AACVD) uses a liquid-gas aerosol to transport soluble precursors to a heated substrate. The method has traditionally been used when a conventional atmospheric pressure CVD precursor proves involatile or thermally unstable. Precursors designed specifically for AACVD may include those that are too involatile or thermally unstable for conventional CVD, enabling investigation of new precursors and films. Ionic precursors and metal oxide clusters have been used in aerosol assisted depositions as alternative routes to thin films.

Noble metal colloids may appear to be the antithesis of a CVD precursor, which would normally be a volatile molecule, but the present inventors have shown that pre-formed gold nanoparticles can be transported in an aerosol generated ultrasonically and can therefore be deposited by AACVD. Nanoparticles can either be deposited alone, yielding nanoparticle films, or together with a conventional CVD precursor (which forms a host matrix in which the nanoparticles are embedded), yielding nanocomposite films. Use of pre-formed nanoparticles is advantageous because a wider range of nanoparticles can be used.

### SUMMARY OF THE INVENTION

In one aspect of the invention there is provided the use of an aerosol transport operation for producing a nanoparticle film or a nanocomposite film on a substrate, wherein the substrate is heated.

In particular, the invention provides a process for producing a nanoparticle film or a nanocomposite film on a substrate, wherein the film is deposited using an aerosol and the substrate is heated. The process may comprise the steps of: (i) providing a precursor solution comprising nanostructures; (ii) forming an aerosol of the solution; and (iii) deposition onto a heated substrate.

AACVD is a particularly suitable technique to be used for use in the present invention.

In another aspect of the invention, nanoparticle films or nanocomposite films obtainable by the process of the invention are provided.

In another aspect, the present invention provides a gold nanoparticle film or a nanocomposite film comprising gold nanoparticles, characterised in that it exhibits dichroism.

In yet another aspect the present invention provides use of the films of the invention as a heat mirror, a window coating or for differential reflection and transmission of solar energy at different wavelengths. In other aspects the films may also be used in self-cleaning applications or as anti-microbial coatings.

As used herein, the term “film” is intended to refer to a contiguous layer of nanostructures (e.g. a “nanoparticle film”) or of a host matrix in or upon which nanostructures are deposited (e.g. a “nanocomposite film”). Such films (especially when relatively thick) may be subject to shrink-cracking, such that they are not completely continuous on a microscopic scale. When formed by a vapour phase deposition process, the deposited layer grows from many seed points and thus the film will contain separate domains or “islands”, with boundaries between such domains. The films nevertheless appear continuous on a macroscopic scale.

### DETAILED DESCRIPTION OF THE INVENTION

### Nanostructures

Any known nanostructures may be deposited as films according to the present invention. The term nanostructures is generally understood to mean structures of from 1 to 100 nm in size. These may be, for example, nanoparticles, alloys or complex structures. The term also encompasses quantum dots, namely particles of, for example, cadmium sulfide, which are capable of absorbing light and re-emitting it at a longer wavelength.

Nanoparticles typically, but not exclusively, comprise metals. In particular, main group metals and transition metals are suitable for the process of the present invention. In some aspects of the invention, preferred metals include gold, silver and copper.

Nanostructures may also comprise alloys of two or more metals, for example any two or more of the metals mentioned above. Particularly preferred alloys include gold/silver, gold/copper, silver/copper and gold/silver/copper.

Complex nanostructures may be in the form of, for example, core-shell particles, rods, stars, spheres or sheets. A core-shell particle may typically comprise a core of one substance, such as a metal or metal oxide, surrounded by a shell of another substance, such as a metal, metal oxide or metal selenide. Other shaped complex nanostructures may comprise metals, such as those mentioned above.

### Nanostructure Precursor Solution

Any solution comprising nanostructures is suitable for the process of the present invention. Such a precursor solution for providing nanoparticles for deposition may be prepared according to any suitable technique. A well-known technique for the production of nanoparticles is reduction in solution. For example, a metal colloid solution comprising metal nanoparticles may be prepared by the Brust two-phase reduction method, which was initially described for use in preparing gold metal colloids, and has since been extended to the production of nanoparticles of other metals.

The solution may also contain host matrix precursors, as described further below.

The concentration of nanostructures in the deposited film can be altered simply by changing the concentration of nanostructures in the precursor solution. The concentration of nanostructures in the precursor solution may vary from 1 μg L⁻¹ to 10 g L⁻¹. The lower concentration of nanostructures would normally be used together with higher concentrations of a host matrix precursor to provide a nanocomposite film comprising very low (i.e. dopant) levels of the nanostructure. At concentrations above 10 g L⁻¹, dispersions of nanostructures in precursor solutions tend to become unstable, and are less suitable for the process of the invention.

Preferably, the concentration of nanostructures in the precursor solution is from 0.5 to 1.5 g L⁻¹, more preferably from 0.7 to 1.0 g L⁻¹. When preparing a nanocomposite film, the concentration of nanostructures in the precursor solution is preferably such that the deposited host matrix comprises 1 to 4% of the nanostructures. In another embodiment, the deposited film comprises 0.1 to 20 mol % or even up to 25 mol % of nanostructures, preferably 5 to 10 mol %, for example 5 mol %. The film may optionally comprise components other than the host matrix and nanostructures. In a preferred form the film consists of from 5 to 10 mol % by weight of the nanostructures and 95 to 90 mol % of the host matrix.

Nanostructure solutions, preferably metal colloids, are generally stabilized in order to prevent aggregation of the nanostructures. Preferably, nanostructure precursor solutions are charge-stabilized. In principle, capping groups, such as thiol capping groups, may be used. This is not preferable, however, since it may lead to contamination of the deposited films.

Since nanostructure solutions in solvents other than water degrade over time, it is preferable to use such solutions within three weeks of preparation. More preferably, the solutions are used within one week of preparation, more preferably within 2 days. Most preferably, depositions are carried out using colloids made on the same day.

Any suitable solvent may be used for the nanostructure precursor solution. When a metal nanoparticle film is required, it is preferable that water is used as the solvent, for reasons of solution stability. When preparing a nanocomposite film, it is more preferable to use a solvent which is the same as or compatible with the solvent used for the host matrix precursor, such as an organic solvent, as discussed below.

### Host Matrix

Any known host matrix may be deposited with the nanostructures as described above to form the nanocomposite films of the present invention.

Examples of the host matrix are nitrides, phosphides, oxides, sulphides, selenides, tellurides, carbides, silicides and germanides, i.e. compounds of N, P, O, S, Se, Te, C, Si or Ge and another element or group, usually a more electropositive element.

The more electropositive element in the above compounds may be, for example, a main group metal, transition metal, lanthanide or actinide. Specific examples that are suitable for the present invention are tin, gallium, indium, aluminium, silicon, titanium, tungsten, copper or zinc, or mixtures of these.

The host matrix may preferably be, for example, titanium dioxide (TiO₂), tungsten oxide (e.g. WO₃), copper oxide (CuO), zinc oxide (ZnO), indium tin oxide (InSnO₃), silicon dioxide (SiO₂), tin oxide (SnO₂) and indium oxide (In₂O₃).

### Host Matrix Precursor Solution

The host matrix precursor solution may be any suitable to deposit a host matrix as described above. For example, these precursors may be any suitable for conventional CVD applications.

Preferred precursors are metal complexes having at least one ligand selected from alkoxide, aryloxide, CO, alkyl, amide, aminyl, diketones.

Suitable ligands comprise a group R attached to an element which is to be incorporated in the deposited host matrix, such as oxygen. It is preferred that the group R is short, for example C₁₋₄, or has a good leaving functionality.

Examples of alkoxide ligands are C₁₋₆ alkoxide such as ethoxide, preferably C₁₋₄ alkoxide most preferably isopropyloxide (OⁱPr) or tertiary-butyloxide (O^{t}Bu). The aryloxide is preferably substituted or unsubstituted phenoxide, preferably unsubstituted phenoxide. Examples of alkyl groups are C₁₋₄alkyl, such as methyl and ethyl. Examples of amide are R¹CONR²₂, where each R¹ and R² is each independently H or C₁₋₄alkyl. Examples of aminyl are NR¹₂ where R¹ where R¹ is as defined above. Examples of diketones include pentane-2,4-dione.

Preferably, all ligands are selected from these groups. Most preferably, the coordination sphere around the metal contains all oxygen or all nitrogen.

Suitable ligands may contain all of the elements required for incorporation in the deposited host matrix. Alternatively, the host matrix precursor may be used with a co-source of the required element. For example, when a CO ligand is used, a co-source of oxygen may be supplied by using an alcohol solvent or providing oxygen to the system.

Preferred examples of the host matrix precursor include tungsten (VI) phenoxide ([W(OPh)₆]) and titanium (IV) isopropoxide [Ti(OⁱPr)₄].

Any suitable solvent may be used for the host matrix precursor solution, preferably an organic solvent, although water may be used. It is important in the process of the present invention that the precursor is highly soluble in the chosen solvent, most preferably completely soluble. The solvent must be capable of forming an aerosol.

Preferably, the solvent is toluene, benzene, hexane, cyclohexane, methyl chloride, acetonitrile. A mixture of two or more different solvents may be used, provided the solvents are miscible. Most preferably, the solvent is toluene.

The molar ratio of the nanostructure provided by the nanostructure precursor to the amount of host matrix precursor may be from 1:1000 to 2:1. Typical molar ratios of the nanostructure provided by the nanostructure precursor to the amount of host matrix precursor are from 1:30 to 1:5. Preferably, the ratio of nanostructure to host matrix precursor is from 1:3 to 1:10.

### Formation of an Aerosol

An aerosol may be generated from the nanostructure precursor solution, together with the host matrix precursor solution if used, using any suitable technique. For example, an aerosol may be generated ultrasonically or by nebulisation.

For ultrasonic generation, the solution is typically placed in an ultrasonic humidifier at high frequency. The frequency required for aerosol generation depends on the solvent used. Typically, a frequency of 10 to 100 kHz is used, preferably 20 to 70 kHz, more preferably 30-50 kHz. The solution may be placed directly in contact with the piezoelectric crystal of the ultrasonic humidifier, or alternatively placed in a container, such as a thin plastic container or glass flask in which the base has been thinned to around a quarter of the usual thickness.

Nebulisation to form an aerosol may be achieved, for example, using the top of a conventional spray can or a nebuliser of the type typically used for asthma medication.

Deposition onto a Heated Substrate

The aerosol of the precursor solution(s) is directed towards the substrate using a flow of a transport gas. This may be an inert gas, preferably nitrogen. Alternatively a gas suitable to provide a co-source of an element to be incorporated in the deposited host matrix may be used. For example, oxygen gas may be used to provide an oxide coating. Mixtures of gases may be used, such as nitrogen and hydrogen or nitrogen and oxygen.

Films are typically deposited at a substrate temperature of from 150 to 700° C. The substrate temperature chosen depends on both the apparatus and the type of precursors used. At substrate temperatures below 150° C., the deposited films lack sufficient adhesion to the substrate. At temperatures above 700° C., undesirable side-reactions may occur. In an AACVD apparatus, the substrate temperature is preferably from 400 to 650° C., more preferably 400 to 550° C. In a float glass production line, the substrate temperature is preferably from 550 to 700° C., more preferably from 550 to 650° C.

After deposition, the substrate is allowed to cool to room temperature.

Preferably, the process is carried out using AACVD. Using this technique, a precursor is transformed into an aerosol before deposition using a conventional CVD reactor. Examples of suitable CVD reactors are cold-wall horizontal-bed CVD reactors, cold-wall shower-head reactors and hot-wall reactors. Preferably, a cold-wall horizontal-bed reactor is used. A CVD apparatus suitable for use in the present invention is described in Chem. Vap. Dep. 1998, 4, 222-225.

In one particular aspect of the invention, AACVD may be conducted under conditions which allow oxidation.

Provided the substrate is capable of having a nanoparticle or nanocomposite film deposited on its surface, the substrate is not critical to the invention. However, preferred substrates are glass substrates, for example glass slides, films, panes or windows. Particularly preferred glass substrates have a barrier layer of silicon dioxide (SiO₂) to stop diffusion of ions from the glass into the deposited film. Typically, the silicon dioxide (SiO₂) barrier layer is 50 nm thick.

Other preferred substrates are temperature-insensitive materials such as metals, metal oxides, nitrides, carbides, silicides and ceramics. Such substrates may be, for example, in the form of windows, tiles, wash basins or taps.

The process of the invention may comprise a further step of annealing the film. Annealing is known to increase film density by eliminating pores and voids, and thus would be expected to reduce particle separation. The time and temperature of annealing depends on the substrate. Typically, films may be annealed by heating in air at a temperature of from 300 to 700° C., preferably 400 to 600° C., more preferably 450 to 550° C., for between 20 minutes and 2 hours.

To the best of the applicant's knowledge, in all current CVD processes that deposit nanoparticles or nano-structures in general (e.g. rods, wires, tubes etc.), the nano-objects form in the CVD reactor itself from the reaction of one or more precursors. In all these cases, the deposition conditions must be controlled to ensure the correct size and shape of nano-object is formed. The aerosol assisted method presented here is unique in using pre-formed nanoparticles as precursors for CVD. As such, the nanoparticle synthesis is distinct from the deposition step, so that deposition parameters do not need to be tailored to accommodate nanoparticle formation and each can be individually optimized, although the transport of nanoparticles to the substrate must still be considered. It is expected that nanoparticles of complex compositions and shapes might be used, such as core-shell particles or alloys, which will be difficult to produce in situ in a CVD reactor.

There are two main benefits to the new process over existing techniques. Firstly, it is flexible; many pre-formed nanoparticle solutions may be used, and combined with any chemically compatible conventional precursor, to produce a large range of nanocomposite films. Secondly, CVD is a widely used industrial technique in fields such as microelectronics and window glass coating, and has a number of well known advantages, not least the deposition of adherent, conformal films. Nanocomposite films with these qualities can now be easily and inexpensively produced by the process presented here. The process can be easily incorporated into float glass production lines, and has fast growth times, deposition taking from 1 second to 1 minute. The process of the present invention uniquely uses pre-formed particles and a single-step deposition.

### Films According to the Invention

The nanoparticle films obtainable by the process of the present invention preferably have a thickness of from 25 to 200 nm, preferably from 30 to 150 nm, more preferably from 50 to 100 nm.

The nanoparticle film obtainable by the process of the invention is preferably a gold nanoparticle film.

The nanocomposite films obtainable by the process of the present invention preferably have a thickness of from 25 to 1000 nm, preferably from 50 to 500 nm, more preferably from 100 to 400 nm.

Preferred examples of nanocomposite films obtainable by the process of the invention are those wherein the host matrix comprises a metal oxide. Particularly preferred are nanocomposite films wherein the host matrix comprises titanium dioxide (TiO₂), tungsten oxide (e.g. WO₃), copper oxide (CuO), zinc oxide (ZnO) or indium tin oxide (InSnO₃) and the nanoparticles comprise silver, silver alloy and/or silver oxide. Such films may be used in self-cleaning applications or as anti-microbial coatings, for example when deposited on a metal or ceramic substrate. Such films having an antimicrobial effect are not only capable of destroying or inhibiting the growth of microorganisms, but may also be effective against agents such as prions.

The antimicrobial effect of the films is activated by exposure to a light source. In one embodiment, the films may be exposed to a light source comprising radiation having a wavelength, or a range of wavelengths, within or corresponding to the bandgap of the host matrix in the film. In general, radiation having wavelength(s) of 385 nm, preferably 380 nm, or lower is preferable. For example, sunlight, approximately 2% of which is radiation of 385 nm or lower wavelength, is a suitable light source. Exposure to ambient lighting, such as indoor lighting, is also sufficient to provide the antimicrobial effect, provided the light source is not covered in plastic or other material such that radiation having a wavelength less than or equal to the host matrix bandgap is absorbed or prevented from reaching the film.

Particularly effective films of the present invention have very low contact angles, providing surfaces with good wettability. Surfaces coated with such films therefore have good drainage properties and are suitable for self-cleaning applications. Preferred films are superhydrophilic, having contact angles of 10° or less, even of zero.

The self-cleaning/antimicrobial properties of nanocomposite films, such as the nanocomposite films of the present invention described above, may find application in hospitals and other places where microbiological cleanliness is necessary, for example food processing facilities, dining areas or play areas. The films may be applied to any suitable surface in order to provide antimicrobial properties, for example metal surfaces such as taps and metal work surfaces, ceramic surfaces, such as wash basins and toilets or glass surfaces, such as doors and windows. It is also envisaged that the films could be applied to furniture, such as beds, or medical equipment and instruments. For such applications nanocomposite films based on silver, silver alloy and/or silver oxide nanoparticles are preferred. In one aspect, the present invention does not extend to the use of the films in methods of treatment of the human or animal body by surgery or therapy, or in methods of diagnosis conducted on the human or animal body.

Nanocomposite films comprising silver and/or silver oxide in a titanium dioxide host matrix are particularly preferred for self-cleaning/antimicrobial applications. In films deposited by AACVD, oxidation of silver nanoparticles can take place as a result of residual oxygen in the materials, such as the substrate. Thus it is not necessary for oxygen to be provided to the system in order for oxidation to occur. The nanoparticles deposited by AACVD may comprise a core of silver surrounded by at least a layer of silver oxide, or they may consist entirely of silver oxide.

In another embodiment, preferred nanocomposite films obtainable by the process of the invention are those wherein the host matrix comprises an oxide or nitride, particularly in combination with nanoparticles comprising a metal having surface plasmon resonance, such as gold, silver, copper or an alloy thereof. A nanocomposite film comprising a silicon dioxide (SiO₂) or tin oxide (SnO₂) host matrix and gold nanoparticles is particularly preferred. Such films may be used as functional window coatings, for example as heat mirrors or to provide colour effects, such as differential reflection and transmission of solar energy at different wavelengths. The optical haze of these films is preferably less than 1%. Commercial window coatings typically have below 1% optical haze.

The process of the present invention produces gold nanoparticle films and nanocomposite films comprising gold nanoparticles which demonstrate interesting colour and optical spectra. These characteristics are dominated by the plasmon resonance of the gold nanoparticles incorporated within the films. The plasmon peak is red shifted on deposition, and demonstrates further red shifting on annealing of the films.

Such films comprising gold nanoparticles exhibit dichroism, meaning that they appear different colours in transmitted and reflected light. For example, such films may appear red in reflected light and blue in transmitted light.

This dichroism may also be observed as a local minimum in the transmission spectrum of the film at from 550 to 610 nm, together with a peak in its reflectance spectrum at from 780 to 820 nm.

The colour of the films may be quantified using the CIELAB colour coordinates, which are used to express perceived colour and are an industry standard. Two parameters, a* and b*, define the colour: positive a* values correspond to red, negative a* values to green. Positive b* values correspond to yellow, negative b* values to blue. The CIELAB colour coordinates of the gold/titania nanocomposite films preferably have the following relationship:

a*(R)=−0.75a*(T) to −1.25a*(T) and

b*(R)=0.5b*(T) to 2.0b*(T),

wherein a* (R) and b*(R) correspond to the values for reflected light, and a*(T) and b*(T) correspond to the values for transmitted light.

The colour effects provided by the gold nanoparticles arise because the plasmon absorption band is at about 520 nm and depend on the proportion of nanoparticles in the film. The colour effects described above are observed only at low concentrations. At nanoparticle concentrations of greater than 4%, the film appears gold.

The colour-inducing effects of silver and copper nanoparticles are expected to be less than is seen with gold nanoparticles because the plasmon absorption band is at the edge of the visible spectrum. It may be that doping the nanoparticles or use of copper or silver alloys will enhance the effects by modifying the plasmon absorption band.

The reflection properties of films of the present invention comprising gold nanoparticles may be useful in heat mirror applications, since these films reflect infra red light and transmit visible light. Heat mirrors are used in solar control applications. In this case the higher reflectivity in the near IR would mean that a window incorporating these particles would reflect away much of the heat portion of solar radiation (which is most intense between ca 800-1500 nm). This would enable a reduction in solar gain and a reduction in air conditioning costs. The optical clarity of the films makes them suitable for use as window coatings where tinted glass is required. This would be a valuable alternative to body tinting—the current practice of colouring the whole pane of glass—as it is an expensive process to implement on a glass float line. A coating that gave the same intensity in colour, and whose colour could be varied by a simple change in precursor concentration, may make tinted glass much less expensive to produce.

The process of the present invention, in particular the process comprising using AACVD, is particularly advantageous, because films may be deposited onto any suitable substrate. Since the coating layer conforms to the surface of the substrate, the substrate is not limited as to its shape, size or conformation. Another advantage is that the deposited films, in particular nanocomposite films, have good durability, forming tenacious coatings that are not easily wiped or otherwise removed from the surface of the substrate.

### EXAMPLES

### Examples 1 to 3

### Preparation of Nanoparticle/Nanocomposite Films Precursor Synthesis

All chemicals were purchased from Aldrich Chemical Company, and used as received without further purification. Gold colloids were synthesised in toluene using the Brust two-phase chemical reduction method. Hydrogentetrachloroaurate (HAuCl_{4.}3H₂O; (99%, 0.17 g) was dissolved in deionised water (15 mL). Tetraoctylammonium bromide (TOAB) (99%, 1.04 g) was dissolved in toluene (40 mL), and the two solutions stirred together. A solution of sodium tetrahydroborate (NaBH₄, 0.19 g) in deionised water (25 mL) was added dropwise with rapid stirring over a 30 min period, yielding a dark red organic layer. This was separated, washed with portions of dilute aqueous sulphuric acid (H₂SO₄) and water, dried over sodium sulfate (Na₂SO₄ ) and diluted to 100 mL volume with toluene, yielding a dark red solution. The concentration of gold was 4.3 mmol atoms L⁻¹, 0.85 g L⁻¹. To avoid contamination of films deposited from these solutions, thiol capping groups were not used. As a result, the colloids degraded over time, changing from deep red on synthesis to pale purple or colourless within three weeks when stored at 4° C. To minimise the effect of colloid degradation on the resulting films, all depositions were carried out using colloids made on the same day. Tungsten phenoxide was synthesised as we have previously described, through the reaction of tungsten (VI) chloride (WCl₆) with phenol in toluene. Titanium (IV) isopropoxide ([Ti(OⁱPr)₄]; 97%) was purchased from Aldrich and used as supplied.

Aerosol Assisted CVD. Depositions were carried out in a cold-wall horizontal-bed CVD reactor. A substrate and top-plate were used, both of silicon dioxide (SiO₂) barrier glass of dimensions 145×45×5 mm. Deposition was carried out on the silicon dioxide (SiO₂) barrier layer in order to prevent migration of ions into the film from the glass bulk. The substrate rested on a carbon heating block powered by a Whatmann cartridge heater, the temperature was monitored by Pt-Rh thermocouples. A top-plate was positioned parallel to the substrate and 8 mm above it, and the whole assembly was contained within a quartz tube. An aerosol was generated from the precursor solution in a glass flask using a Pifco ultrasonic humidifier with an operating frequency of 40 kHz. The aerosol was directed to the reactor by nitrogen gas through PTFE and glass tubing, entering the reactor between the top-plate and substrate; reactor waste left via an exhaust port. The gas flow was continued until all the precursor mix had passed through the reactor, typically taking 20 to 30 minutes depending on the gas flow rate. Films were cooled in situ under a flow of nitrogen gas, and subsequently were handled and stored in air.

TABLE 1
Parameters used to deposit nanoparticle and nanocomposites
thin films on glass using aerosol assisted CVD.

| | Volume of | Precursor, | | | |
|---|---|---|---|---|---|
| Film | gold colloid | amount | Molar ratio | | Na flow rate/ |
| number | used/mL | (mmol) | Au:precursor | Solvent | L min⁻¹ |
| 1 | 5.0 | none | — | toluene, | 1.0 |
| | | | | 20 mL | |
| 2 | 5.0 | W(OPh)₆ | 2:1 | toluene, | 1.0 |
| | | 1 mmol | | 20 mL | |
| 3 | 0 | Ti(OⁱPr)₄ | — | toluene, | 2.0 |
| | | 1 mmol | | 20 mL | |
| 4 | 1.0 | Ti(OⁱPr)₄ | 1:2 | toluene, | 2.0 |
| | | 1 mmol | | 20 mL | |
| 5 | 2.0 | Ti(OⁱPr)₄ | 1:1 | toluene, | 2.0 |
| | | 1 mmol | | 20 mL | |
| 6 | 4.0 | Ti(OⁱPr)₄ | 2:1 | toluene, | 2.0 |
| | | 1 mmol | | 20 mL | |

All depositions were carried out at 450° C.

Depositions of thin films on glass were carried out as shown in Table 1. Three types of film were deposited: gold nanoparticle films from the gold nanoparticle solution alone (film 1), tungsten oxide (e.g. WO₃)/ Au composite films from tungsten (VI) phenoxide ([W(OPh)₆]) and gold nanoparticle solution (film 2) and titanium dioxide (TiO₂)/Au composite films from titanium (IV) isopropoxide ([Ti(OⁱPr)₄]) and gold nanoparticle solution (films 4,5,6). A series of titania films with different concentrations of gold nanoparticles were deposited. The flow rates and volumes of solvent used were selected to give the most extensive deposition over the substrate.

Analysis. X-ray photoelectron spectroscopy (XPS) measurements were carried out on a VG ESCALAB 220i XL instrument using monochromatic Al Kα radiation. Binding energies were referenced to surface elemental carbon 1 s peak with binding energy 284.6 eV. UV/vis spectra were obtained using a Thermo Helios-α spectrometer.

Where a solution spectra was taken, quartz cuvettes with a path length of 1 cm were used. Scanning Electron Microscopy (SEM) and Energy Dispersive X-Ray (EDX) analysis was carried out using a JEOL 6301F instrument using voltages between 6 and 15 kV, at 8 ∝A. Before SEM analysis, samples were sputter coated with gold using an Edwards S150B sputter coater, operating at 1.5 kV and 20 mA. Transmission Electron Microscopy (TEM) was performed on gold nanoparticle solutions, and was carried out on a Jeol JEM 100CX II. TEM samples were prepared by evaporating a single drop of the sample onto a conducting copper mesh. Powder X-ray diffraction (XRD) patterns were obtained on a Bruker AXS D8 instrument using CuKα radiation. To record diffraction peaks from the thin films, a fixed incidence angle of 5° was used. Diffraction patterns were recorded with an area detector. Colour data, reflectance/transmittance spectra and haze measurements were recorded on a HunterLab UltraScan Pro instrument. Colour analysis was performed at 2° viewing angle using D65 artificial daylight, which was also used for haze measurements.

Results. The initial stock gold nanoparticle solutions used was deep red in colour. Their UV/vis spectrum showed a plasmon resonance peak with maximum at 533 nm. TEM revealed a mean diameter of 10 nm and narrow particle size distribution.

### Example 1

### Gold Nanoparticle Films

The deposition of gold nanoparticles from gold colloid solutions occurred on both the substrate and top plate, which is the glass plate that rests 8 mm above the surface of the substrate. Films deposited on the substrate were used in the analysis described below. Gold nanoparticle films appeared red to transmitted light and yellow to reflected light. The films were stored and handled in air with no apparent degradation, however the films were non-adherent and could be easily removed by slight mechanical abrasion. The glass could be wiped completely clean with a tissue, indicating that the gold particles were weakly adsorbed on the glass surface, rather than strongly bound to it or absorbed within it. UV/visible spectroscopy revealed the characteristic gold plasmon resonance peak, with a maximum at 538 nm. This was very similar in position and shape to the plasmon peak observed in the initial gold nanoparticle solution, which had a maximum at 533 nm, suggesting that the mean size and shape of the particles are roughly similar to that of the precursor colloid. Au 4 f 7/2 and 5/2 peaks at binding energies of 87.5 eV and 83.7 eV respectively, corresponding to metallic gold, were observed by XPS. SEM confirmed the presence of individual nanoparticles on the surface of the film. The particles appear randomly distributed, roughly spherical, and around 50 nm in diameter. Some particles seem to be agglomerates of two, three or more smaller particles. In other places, two or three particles can be observed in close proximity but not conjoined. Bare glass is visible between the particles, showing that less than one monolayer has been deposited. Assuming the particles to be spherical, this places the maximum film thickness at 50-100 nm, the diameter of a single particle.

The apparent increase in particle size could be due to agglomeration of particles, either in the gas phase or on the substrate surface. In either case, it is significant that the deposition yields a nanoparticulate film rather than a continuous metal film or highly agglomerated particles, which might be expected due to the associated energetically favourable reduction of surface area and the relatively high temperature of deposition. No nitrogen or bromine peaks were observed in the XPS spectrum, indicating that atoms from the tetraoctylammonium bromide used in the synthesis, which prevented particle agglomeration in solution, are no longer present. This suggests that the gold particle mobility on the surface is low, even at the deposition temperature, preventing aggregation and continuous film formation.

### Example 2

### Titania (Titanium Dioxide; TiO₂)/Gold Nanocomposite Films

Titania (titanium dioxide; TiO₂) films were deposited with 1, 2 and 4 mL of 4.3 mM gold nanoparticle solution (Table 1). The molar ratios of Ti:Au used in each experiment were approximately 1:2, 1:1, 2:1 respectively. All films were deposited at a substrate temperature of 450° C. The films differed in thickness throughout the substrate, but samples taken for analysis were approximately 300 nm in thickness, determined by the pattern of interference fringes. Undoped titania films produced by CVD are typically colourless or pale yellow. Titania (titanium dioxide; TiO₂)/gold composite films appeared pale blue to transmitted light, the intensity of the blue colour increasing with increasing gold nanoparticle content. All titania (titanium dioxide; TiO₂) composite films were strongly adherent to the glass, such that they could not be removed by vigorous rubbing with tissue paper and were undamaged in routine handling. Application of pressure with a stainless steel stylus caused small portions of the film to chip away. Optical haze, being the percentage of D65 artificial daylight scattered by the films, was measured to be 0.40%, 0.55% and 0.75% for 4, 5, 6 respectively.

UV/vis spectroscopy of the titanium dioxide (TiO₂)/Au composite films showed absorption maxima at 570 to 600 nm with a bathochromic shift with increasing Au concentration. These absorption peaks in the region of 580 nm are assigned to the red shifted and broadened plasmon resonance of gold nanoparticles.

The gold nanoparticles could not be removed from the titanium dioxide (TiO₂)/Au composite film by immersion in common organic solvents or water, or by abrasion, as indicated by the persistence of the plasmon absorption peak after these treatments. Indeed, the gold particles could not be removed by any physical method that did not also remove the titania film, showing that the nanoparticles are either strongly bound to the film or firmly contained within it.

The intensity of the plasmon absorption in the titanium dioxide (TiO₂)/Au films increased with increasing gold concentration. The reflectance/transmission spectrum of the highest concentration composite film was measured in the visible and IR regions. The plasmon peak was seen as a local minimum in the transmission spectrum at 580 nm, and the titania band edge was present at 390 nm. Other than these two features, the transmission spectrum was qualitatively that of the float glass substrate. The reflectance spectrum showed a highly unusual broad peak in the red and near infrared region with a maximum at 805 nm, where 35% of incident light was reflected. This feature is not characteristic of titania or glass, so must arise from the gold particles.

The colour of the gold/titania nanocomposite films was quantified using the CIELAB colour coordinates. Table 2 shows the colour of the high concentration titanium dioxide (TiO₂)/Au composite thin film to both transmitted and reflected light. Transmitted light was blue-green, while reflected light was red, which was consistent with the visible spectra. For comparison, data is given for 5 mm thick sheets of transition metal doped (body tinted) glass. Untreated glass has close to no colour (a* and b* are close to zero), while Fe and Nd doped glasses are strongly coloured. Significantly, the intensity of transmitted colour imparted by the composite film was comparable to commercial body tinted glass, despite the film being around four orders of magnitude thinner; the extinction coefficients of gold particles are known to be greater than typical organic or transition metal dyes. These films might therefore be used as coloured coatings with a colouration of similar magnitude to traditional body tinted glass. Furthermore, the near symmetric opposite colouration of these films in reflected and transmitted light is unusual. This type of dichromism has been seen in bulk materials that contain a dispersion of metal nanoparticles.

TABLE 2
Colour space representation of the colour of light reflected
by a titanium dioxide/gold nanocomposite film.

| Substrate | a* | b* |
|---|---|---|
| TiO₂/Au film (transmission) | −10.5 | −5.0 |
| TiO₂/Au film (reflectance) | 9.0 | −7.5 |
| 1% Fe doped glass | 17.5 | −0.6 |
| 2% Nd doped glass | −19.0 | 8.0 |
| 2% Ce doped glass | 4.0 | −0.9 |
| Untreated glass | 0.2 | −0.2 |

For comparison, the colour of light transmitted through 5 mm of untreated glass, and 5 mm of glass treated with various concentrations of transition metal ions. The a* values quantify red and green and the b* values quantify yellow and blue.

SEM imaging of the titanium dioxide (TiO₂)/Au films showed bright particles on a darker textured background, interpreted as gold nanoparticles embedded in a titania matrix. The particles appeared randomly distributed and orientated. Some particles had formed larger agglomerations, but the majority were less than 100 nm in diameter. No particles could be seen in the film of lowest concentration, but in films with higher concentrations particles were visible. The particle number density increased with increasing precursor Au concentration, but the particle size distribution was roughly constant. XRD detected crystalline gold in the composite films; peaks at 2θ values of 38.20 and 44.50 (CuKα radiation) arise from the (111) and (200) planes in the Au cubic lattice. The intensity of those peaks increased with increasing gold incorporation, although the width remained approximately constant. The Scherrer equation was used to estimate the gold crystallite diameter using the (111) peak. In the two films of highest gold concentration, this was found to be 10 nm. This diameter is much smaller than the particles observed by SEM, suggesting that each particle is composed of several crystals, most probably several of the original precursor nanoparticles. It appears, therefore, that there is some degree of particle agglomeration at some point during the deposition, either in the gas phase or on the surface of the substrate. However this agglomeration does not change the intrinsic crystallite size of the Au particles—which are unchanged from the initial Au colloid solution. No TiO₂ peaks were observed in the X-ray diffraction pattern, indicating that the deposited titania matrix had low crystallinity. XPS was performed on the titania film with the highest concentration of gold. This confirmed the presence of gold and titanium in the film; a single gold environment was observed with Au 4 f 7/2 and 5/2 peaks at binding energies of 83.4 eV and 87.2 eV respectively, corresponding to Au metal. This shows that the nanoparticles do not undergo a chemical reaction in the CVD process, for example oxidation, and remain metallic.

The titania/gold composite films were annealed in air at 550° C. for 20 min periods. Annealed films appeared a lighter shade of blue than before annealing, and correspondingly the UV/vis absorption maximum shifted to longer wavelengths, became broader and increased in intensity. The greatest change to the optical spectra was seen after 20 min of annealing, and no further change was observed after 80 min. The breadth of the peaks was calculated using the peak half width at ¾ maximum on the low energy (red) side of the peak.

XRD showed that the gold peaks became slightly narrower on annealing; the full width at half maximum (FWHM) of the more intense (111) peak fell by 0.1° for the two films with highest concentration of gold after 20 min at 550° C., indicating a small increase in crystallite size. In contrast, the titania cystallinity increased markedly. Peaks corresponding to anatase phase titania appeared after annealing at 2θ values of 25.90, 48.70 and 54.60. The higher the concentration of gold in the film, the more intense these emergent titania peaks were, although the peak width was similar. The gold particles might act as nucleation sites for titania crystal growth, hence films with a higher number of gold particles show larger amounts of crystalline titania.

### Example 3

### Tungsten Oxide/Gold Nanocomposite Films

To assess whether the method could be extended to other matrix materials, depositions using gold colloid and tungsten hexaphenoxide were carried out (Table 1). Tungsten oxide/gold composite films were dark blue on deposition, due to the presence of reduced tungsten states in a WO₃₋ₓ stoichiometry. Dark blue sub-stoichiometric tungsten oxide has been previously deposited by AACVD, and is not due to the presence of nanoparticles. The films were adherent and continuous, and could not be removed from the glass by vigorous rubbing with a tissue. Application of pressure with a metal stylus caused small portions of the film to chip away. No gold plasmon peak was directly observed in the UV/vis spectrum, although it was probably masked by the strong visible absorption of the tungsten oxide. An XRD pattern, showed cubic gold peaks at 2θ values of 38.80 and 45.10 assigned to (111) and (200) planes. Two strong peaks at 2θ values of 23.90 and 48.50 were assigned to the (020) and (040) reflections of monoclinic WO₃, with strong preferred orientation in the (020) direction, as previously observed in WO₃ films deposited from tungsten (VI) phenoxide ([W(OPh)₆]). The presence of crystalline gold XRD peaks is strong evidence that gold nanoparticles are present in the film as deposited despite the lack of a visible plasmon peak. In addition, SEM imaging showed randomly distributed particles embedded in the tungsten oxide matrix.

The tungsten oxide/gold films were annealed at 450° C. for 20 min. On annealing, the films became pale yellow, corresponding to fully oxidised WO₃. After annealing UV/vis spectroscopy showed a plasmon peak at 604 nm. As with the titania composite films, no method could be found to remove the nanoparticles without also removing the tungsten oxide coating. XRD showed the emergence of monoclinic tungsten oxide peaks absent in the pre-annealed film, although the intensity was lower than the (020) and (040) peaks. No change in the tungsten oxide (020) and (040) peaks was observed. This can be interpreted as the partial randomisation of the crystallite orientation after annealing, although strong preferred orientation remains. As in the titania composite films, the gold peaks did not significantly change on annealing. XPS confirmed the presence of tungsten oxide and gold in the annealed films, showing Au 4 f peaks at 84.3 eV and 88.0 eV. These binding energies were slightly higher than seen in the titanium dioxide (TiO₂)/Au composite, although within the range expected for Au metal nanoparticles. Tungsten was observed in a single environment with W 4 f peaks at 35.9 eV and 38.1 eV, indicating W⁶⁺ ions in WO₃. The lack of W⁴⁺ and W⁵⁺ environments confirms the full oxidation of the tungsten oxide to stoichiometric WO₃ by the annealing process.

1. The use of an aerosol transport operation for producing a nanoparticle film or a nanocomposite film on a substrate, wherein the substrate is heated.

2. Use according to claim 1, wherein the aerosol transport operation is aerosol assisted chemical vapour deposition (AACVD).

3. A process of producing a nanoparticle film or a nanocomposite film on a substrate, wherein the film is deposited using an aerosol and the substrate is heated.

4. Process according to claim 3, comprising using aerosol assisted chemical vapour deposition (AACVD).

5. Process according to claim 3, comprising the steps of:
(i) providing a precursor solution comprising nanostructures; (ii) forming an aerosol of the solution; and
(iii) deposition onto a heated substrate.

6. Process according to claim 5, wherein the precursor solution comprises nanoparticles.

7. Process according to claim 6, wherein the precursor solution comprises a metal colloid solution.

8. Process according to claim 7, wherein the metal is a main group metal or a transition metal .

9. Process according to claim 5, wherein the nanostructures comprise metal alloys.

10. Process according to claim 5, wherein the nanostructures comprise core-shell particles, rods, stars, spheres or sheets.

11. Process according to claim 5, wherein the precursor solution further comprises one or more host matrix precursors to provide a nanocomposite film.

12. Process according to claim 11, wherein the host matrix precursor provides in the deposited host matrix a compound of N, P, O, S, Se, Te, C, Si or Ge and a more electropositive element or group.

13. Process according to claim 12, wherein the more electropositive element comprises a main group metal, transition metal, lanthanide, actinide or silicon.

14. Process according to claim 13, wherein the more electropositive element comprises tin, gallium, indium, aluminium, silicon, titanium, tungsten, copper or zinc.

15. Process according to claim 11, wherein the ratio of metal to host matrix precursor is from 1:3 to 1:10.

16. Process according to claim 5, further comprising a step (iv) of annealing the film.

17. A substrate having a nanoparticle film or a nanocomposite film obtainable by the use of claim 1.

18. A nanoparticle film obtainable by the use of claim 1.

19. A nanoparticle film according to claim 18, comprising gold nanoparticles.

20. A nanocomposite film obtainable by the use of claim 1.

21. A nanocomposite film according to claim 20, wherein the host matrix comprises a metal oxide.

22. A nanocomposite film according to claim 21, wherein the host matrix comprises titanium dioxide (TiO₂), tungsten oxide (e.g. WO₃), copper oxide (CuO), zinc oxide (ZnO) or indium tin oxide (InSnO₃) and the nanoparticles comprise silver, silver alloy and/or silver oxide.

23. A nanocomposite film according to claim 21, deposited on a substrate comprising metal or ceramic.

24. A nanocomposite film according to claim 20, wherein the host matrix comprises an oxide or nitride.

25. A nanocomposite film according to claim 24, wherein the nanoparticles comprise silver, gold, copper, or an alloy comprising gold/silver, gold/copper, silver/copper or gold/silver/copper.

26. A nanocomposite film according to claim 24, having an optical haze of less than 1%.

27. A nanocomposite film according to claim 24, deposited on a substrate comprising glass.

28. A nanocomposite film according to claim 27, wherein the substrate comprises SiO₂ barrier glass.

29. A gold nanoparticle film or a nanocomposite film comprising gold nanoparticles, characterised in that it exhibits dichroism.

30. A film according to claim 29, wherein the CIELAB colour coordinates have the relationship a*(R)=−0.75a*(T) to −1.25a*(T) and b*(R)=0.5b*(T) to 2.0b*(T), wherein a*(R) and b*(k) correspond to the values for reflected light, and a*(T) and b*(T) correspond to the values for transmitted light.

31. A film according to claim 29, wherein the film is red in reflected light and blue in transmitted light.

32. A film according to claim 29, having a minimum in its transmission spectrum of from 550 to 610 nm, and a peak in its reflectance spectrum at from 780 to 820 nm.

33. A substrate having a film according to claim 29 deposited thereon.

34. A window comprising a substrate of claim 33.

35. A heat mirror comprising a substrate of claim 33.

36. Use of a film according to claim 20, as a heat mirror, a window coating or for differential reflection and transmission of solar energy at different wavelengths.

37. Use of a film according to claim 21 in self-cleaning applications.

38. Use of a film according to claim 21 as an anti-microbial coating.

39. Use of a film according to claim 38 wherein the film comprises a metal oxide and the nanoparticles comprise silver, silver alloy and/or silver oxide.

40. Use according to claim 38, wherein the film is exposed to a radiation having a wavelength or wavelengths less than or equal to the band gap of the host matrix in the film.
